(19) United States
(12) Patent Application Publication
(10) Pub. No.: US 2018/0166212 A1
(43) Pub. Date: Jun. 14, 2018

(54) ELECTROSTATIC SHIELD

(71) Applicant: ABB Schweiz AG, Baden (CH)

(72) Inventors: William Edward Pauley, Bland, VA (US); Henry Blake Cooke, Wytheville, VA (US)

(21) Appl. No.: 15/379,370

(22) Filed: Dec. 14, 2016

(51) Int. Cl. H01F 27/36; H05K 9/00

(52) U.S. Cl. CPC H01F 27/362; H05K 9/0067

(57) ABSTRACT

A shield member that is configured to prevent the partial discharge of an accumulated electrical charge that buildup or accumulate at or around edge surfaces of the shield member, including, for example, at or around the surfaces and/or relatively sharp corners of cut edge surfaces. The edge surfaces can be offset from ends of the shield member such that the edge surfaces are recessed in an overlapped portion of the shield member. Additionally, the ends of the shield member can provide relatively smooth transition surfaces in the orientation or direction of portions of the shield member, which can prevent or minimize partial discharge of built-up or accumulated electrical charges from the ends of the shield member. The overlapped portions of the shield member can be separated by an insulation body that is configured to prevent short circuiting between the overlapped portions of the shield member.

### BACKGROUND

Embodiments of the present application generally relate to electrical insulation components for electrical power transformers. More particularly, but not exclusively, embodiments of the present application relate to electrostatic shields for electrical power transformers.

Electrical insulation systems in electrical power transformers can include shield members that physically, as well as electrically, generally separate or isolate at least portions of certain components of the transformer from other components of the transformers. For example, shield members, such as, for example, electrostatic shields, can be used to at least attempt to prevent the transfer of surge or impulse voltages between the primary windings and the secondary windings of a transformer.

The configuration of such shield members, including, for example, the general exposure of generally sharp or cut edges, corners, and/or end walls at or along portions of shield members can provide an area(s) or location(s) at which an electric charge can build up or otherwise accumulate on the shield member. In such situations, other components of the transformer that are proximally adjacent to, or generally in relatively close proximity to, the shield member can be exposed to the built-up or accumulated electric charge. Moreover, the built-up or accumulation of electric charge on the shield member can result in at least partial discharge of the electrical charge from the shield member to those other components of the transformer. In at least some instances, over time, such partial discharge of the built-up or accumulated electrical charge to other components can generally result in deterioration, and eventual failure, of those other components. For example, prolong exposure of insulation and/or spacers, among other components of the transformer, including insulation components of the shield member, to such the partial discharge of the built-up or accumulated electric charge from the shield member can cause deterioration of at least some of the materials used in the construction of those components. Over time, such prolong exposure to such partial discharge, and the associated deterioration, can eventually lead to the failure of at least those components, if not failure of other associated components and/or the transformer.

### BRIEF SUMMARY

An aspect of the present application is an apparatus that includes a body portion having a first edge surface and a second edge surface, the first and second edge surfaces being at opposing sides of the body portion. The body portion can be constructed of an electrically conductive material and have a shape that includes a first end and a second end. The first end can be outwardly offset from the first edge surface, and the second end can be outwardly offset from the second edge surface. Further, at least portion of the body portion proximally adjacent to the first end can overlap at least a portion of the body portion proximally adjacent to the second end. The apparatus can also include an insulation body that extends between the overlapped portions of the body portion. Additionally, the apparatus can include a lead that is coupled to the body portion and which is structured to be in electrical communication with an electrical ground.

Another aspect of the present application is an apparatus that includes a body portion having a first elbow portion and a second elbow portion. The body portion can be constructed from an electrically conductive material and include a first edge surface and a second edge surface that are at opposing sides of the body portion. The first elbow portion can comprise a first segment, a second segment, and a first elbow, the first segment extending in a first direction from the first edge surface to the first elbow, the second segment extending in a second direction away from the first elbow. Further, the first direction can be different than the second direction. The second elbow portion can comprise a third segment, a fourth segment, and a second elbow, the third segment extending in a third direction from the second edge surface to the second elbow, and the fourth segment extending in a fourth direction away from the second elbow. Further, the fourth direction can be different than the third direction. Additionally, at least a portion of the first elbow portion can be overlapped by at least a portion of the second elbow portion. The apparatus can also include a lead that is coupled to the body portion and which is structured to be in electrical communication with an electrical ground.

Another aspect of the present application is an apparatus that includes a body portion having a first edge surface and a second edge surface, the first edge surface being inwardly recessed from a first end of the body portion and the second edge surface being inwardly recessed from a second end of the body portion. The first and second ends can each be structured to provide a transition in a direction of the body portion. Further, a first segment of the body portion can extend between the first edge surface and the first end, and a second segment of the body portion can extend between the second edge surface and the second end. Further, at least a portion of the first segment can be overlapped by at least a portion of the second segment. Additionally, the body portion can be constructed from an electrically conductive material. The apparatus can also include an insulation body that is positioned between at least the first segment and the second segment, the insulation body being structured to prevent the transfer of an electrical current between at least the first and second segments.

### BRIEF DESCRIPTION OF THE DRAWINGS

The description herein makes reference to the accompanying figures wherein like reference numerals refer to like parts throughout the several views.

FIG. 1 illustrates a side perspective view of a portion of an exemplary electrical power transformer having a shield member according to an illustrated embodiment of the present application.

FIG. 2 illustrates a schematic representation of a side view of a portion of an exemplary transformer having a shield member according to an illustrated embodiment of the present application.

FIGS. 3A and 3B illustrate a front side perspective view and a side view, respectively, of an exemplary representation of a body portion of a shield member prior to the shield member being shaped for placement in a transformer.

FIG. 4 illustrates a schematic representation of a top view of a portion of an exemplary transformer having a shield member positioned between a low voltage winding assembly and a high/low barrier according to an illustrated embodiment of the present application.

FIG. 5 illustrates a top view of an overlapping portion of a shield member according to an illustrated embodiment of the present application.

FIG. 6 illustrates a side view of a shield member according to an illustrated embodiment of the present application.

The foregoing summary, as well as the following detailed description of certain embodiments of the present application, will be better understood when read in conjunction with the appended drawings. For purposes of illustration, there is shown in the drawings certain embodiments. It should be understood, however, that the present application is not limited to the arrangements and instrumentalities shown in the attached drawings.

### DESCRIPTION OF THE ILLUSTRATED EMBODIMENTS

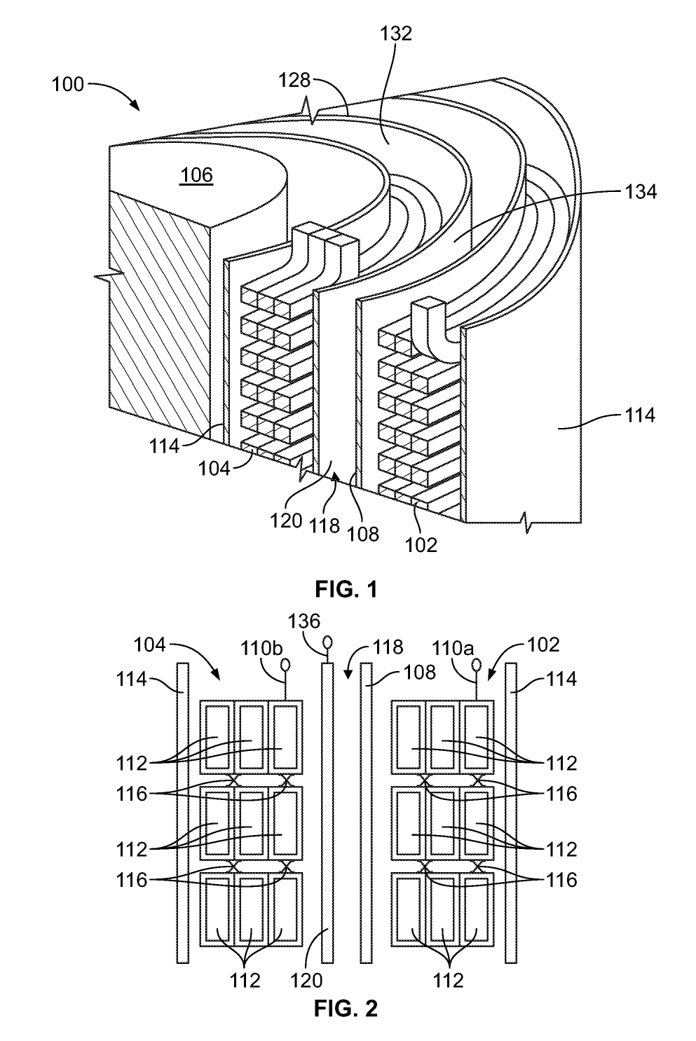

FIGS. 1 and 2 illustrate a side perspective view and a schematic representation of a side view, respectively, of a portion of an exemplary electrical power transformer 100 according to an illustrated embodiment of the present application. As shown, the transformer 100 includes at least one high voltage winding assembly 102 and at least one low voltage winding assembly 104 mounted to a leg of a ferromagnetic core 106. In the illustrated embodiment, the low voltage winding assembly 104 and the high voltage winding assembly 102 are mounted concentrically, with the low voltage winding assembly 104 being disposed radially inward from the high voltage winding assembly 102. The low voltage winding assembly 104 can be separated from the high voltage winding assembly 102 by at least a cylindrical high/low barrier 108, which can be composed of a pressboard or polymeric material, among other materials. While a portion of an exemplary transformer 100 is shown, the transformer 100 can have a variety of configurations. For example, while high and low voltage winding assemblies 102, 104 are shown in FIG. 1 arranged around a portion of a single leg of a ferromagnetic core 106, the transformer 100 can include other legs and associated windings, such as, for example, three low voltage winding assemblies and three high voltage winding assemblies mounted to three core legs, respectively, for a three phase transformer. Further, for example, the ferromagnetic core 106 can have a variety of shapes and configurations.

As shown, according to the illustrated embodiment, one or more leads 110a, 110b can extend from each high and low voltage winding assemblies 102, 104. Further, with respect to the illustrated exemplary embodiment of the transformer 100, each of the high and low voltage winding assemblies 102, 104 can include a plurality of axially arranged rows of disc windings, with each row having one or more disc windings 112. Each disc winding 112 can be constructed from one or more turns of an electrically conductive material or conductor, such as, for example, a conductor composed of copper or aluminum, among other materials. Further, in the illustrated embodiment, each of the high and low voltage winding assemblies 102, 104 can be insulated by an insulation covering 114 that can extend around an outer periphery of at least a portion of the high and low voltage winding assemblies 102, 104. The insulation covering 114 may be constructed from a variety of materials, such as, for example, a non-cellulose based material, such as an enamel coating or a polymeric material, among other materials. Further, at least some of the rows of disc winding 112 can be separated from adjacent rows by one or more spacers 116. Other spacers may also be utilized to separated other components of the transformer 100 and/or insulation(s), such as, for example, spacers that are used to provide spacing for pressure rings, cylinder, and/or winding tables, among other components of the transformer 100.

As previously mentioned, according to the illustrated embodiment, the high and low voltage winding assemblies 102, 104 can be separated from each other by at least a high/low barrier 108. Further, according to certain embodiments, the high/low barrier 108 can be positioned in a space or gap 118 between the high and low voltage winding assemblies 102, 104. Such a gap 118 can be provided in a variety of manners, including, for example, but not limited to, through the use of spacers. Further, the gap 118 can have a variety of sizes, such as, for example, widths and/or diameters, among other sizes, between the low voltage winding assembly 104 and the high voltage winding assembly 102. Factors that can be considered in sizing the gap 118 can include, but is not limited to, the size of components that may be positioned in the gap 118, the ability for air or other cooling mediums to pass through the gap 118 to remove heat from the gap 118, and/or potential for improving impedance for the transformer 100.

According to the illustrated embodiment, a shield member 120, such as, for example, an electrostatic shield, can also be positioned in the gap 118 between the high and low voltage winding assemblies 102, 104. According to certain embodiments, the shield member 120 can be configured to at least prevent and/or minimize the transfer of surge or impulse voltages passing through inter-winding capacitance. While the shield member 120 can be positioned at a variety of locations within the gap 118, according to the illustrated embodiment, the shield member 120 is positioned inside of the high/low barrier 108, such as at a location between the low voltage winding assembly 104 and the high/low barrier 108. However, according to other embodiments, the shield member 120 can be positioned outside of the high/low barrier 108, and, moreover, between the high/low barrier 108 and the high voltage winding assembly 102.

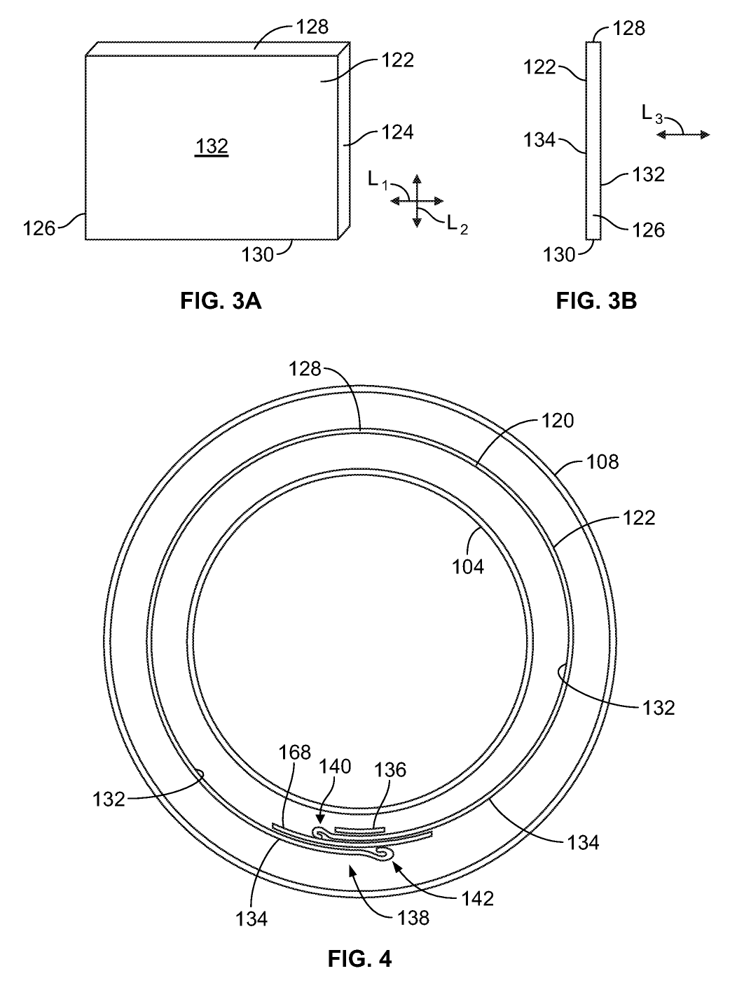

For at least purposes of discussion and illustration, FIGS. 3A and 3B illustrate a front side perspective view and a side view, respectively, of a body portion 122 of an exemplary shield member 120 prior to the shield member 120 being shaped for placement in a transformer 100. While the body portion 122 is illustrated as having a generally rectangular shape, the body portion 122 can have a variety of other shapes, contours, and/or configurations, as well as constructed and/or formed in a variety of different manners. As indicated in the illustrated embodiment, the body portion 122 can have first length (as indicated by the “L₁” direction in FIG. 3A), such as width, between first edge surface 124 and an opposing second edge surface 126 of the body portion 122. Similarly, the body portion 122 can have a second length (as indicated by the “L₂” direction in FIG. 3A), such a height, between a top edge surface 128 and an opposing bottom edge surface 130 of the body portion 122. One or more, it not all, of the first, second, upper, and bottom edge surfaces 124, 126, 128, 130 of the body portion 122 can generally extend between a front side 132 and the opposite rear side 134 of the body portion 122. Moreover, the first, second, upper, and bottom edge surfaces 124, 126, 128, 130 can be cut or otherwise formed surfaces that generally define the boundaries of the body portion 122. Further, according to certain embodiments, the transition between the front and rear sides 132, 134 to the first, second, upper, and/or bottom edge surfaces 124, 126, 128, 130 can occur at, or include, relatively sharp corners and/or edges, among other transitions, that can generally, in at least certain shield member 120 configurations, be susceptible to the buildup of electrical charge when used in a transformer 100.

According to certain embodiments, the first, second, upper, and bottom edge surfaces 124, 126, 128, 130 can have a length (as indicated by the “L₃” direction in FIG. 3B) that is approximately the size of the thickness of the body portion 122, and, moreover, corresponds to the thickness of the body portion 122 between the front side 132 and the rear side 134 of the body portion 122. However, while the edge surfaces 124, 126, 128, 130 depicted in FIGS. 3A and 3B extend in a directions that are generally perpendicular to the front and rear sides 132, 134 of the body portion 122, according to other embodiments, the first, second, upper, and bottom edge surfaces 124, 126, 128, 130, or a portion thereof, can be chamfered or have other surface features such that at least a portion, if not all, of the edge surfaces 124, 126, 128, 130 are not perpendicular to the front and rear sides 124, 126 of the body portion 122, and which can result in a surface length of the one or more of the edge surfaces 124, 126, 128, 130 being different than the thickness (in the indicated “L₃” direction) of the body portion 122.

While FIGS. 3A and 3B illustrate for purposes of discussion the body portion 122, when expanded and/or prior to at least shaping or forming for installation in the transformer 100, as having a generally rectangular shape, the shield member 120 can have a variety of shapes, sizes, and configurations. For example, according to the illustrated embodiments, the shield member 120 may have, or may be manipulated, shaped, or molded, to provide, a shape that is similar to the shape of the gap 118, the low voltage winding assembly 104, the high voltage winding assembly 102, and/or the high/low barrier 108. For example, as shown in at least FIG. 1, according to the illustrated embodiment, the body portion 122 can be formed or shaped to provide the shield member 120 with a generally cylindrical shape, among other shapes. Additionally, the shield member 120 can have a size, including, for example, a diameter and/or length, that generally allows at least the shield member 120 to separate the high and low voltage winding assemblies 102, 104. For example according to the illustrated embodiment, the shield member 120 can have a size, such as, for example, a diameter, that at least encircles at least a portion of the gap 118 so as to separate the high and low voltage winding assemblies 102, 104 in a radial direction, as well as have a length that separates the high and low voltage winding assemblies 102, 104 in an axial direction along a length of the high and low voltage winding assemblies 102, 104.

The shield member 120 can be constructed from a variety of electrically conductive materials or conductors, such as, for example, copper or stainless steel, among other materials. Further, the shield member 120 can be constructed from perforated, non-perforated, or semi-perforated materials. For example, according to certain embodiments, the shield member 120 can be constructed from, among other materials, a non-perforated sheet or foil of conductive material. Alternatively, the shield member 120 can be constructed from a screen material, among other materials, that comprises a conductive material and a plurality of perforations or holes.

As shown in at least FIG. 2, the shield member 120 can include a lead 136 that is configured to electrically couple the shield member 120 to an electrical grounding, or ground. According to certain embodiments, the lead 136 can include an electrically conductive wire or cable, such as, for example, a wire constructed from copper, among other materials. Further, at least a portion of the lead 136 extending from the shield member 120 can be insulated. For example, according to certain embodiments, a portion of the lead 136 extending from the shield member 120 can be encased within an insulated material, such as, for example, a silicon sleeve or coating. The length of the insulated portion of the lead 136 can vary. For example, according to certain embodiments, around ten inches of the portion of the lead 136 that extends from the shield member 120 can be insulated material silicon sleeve

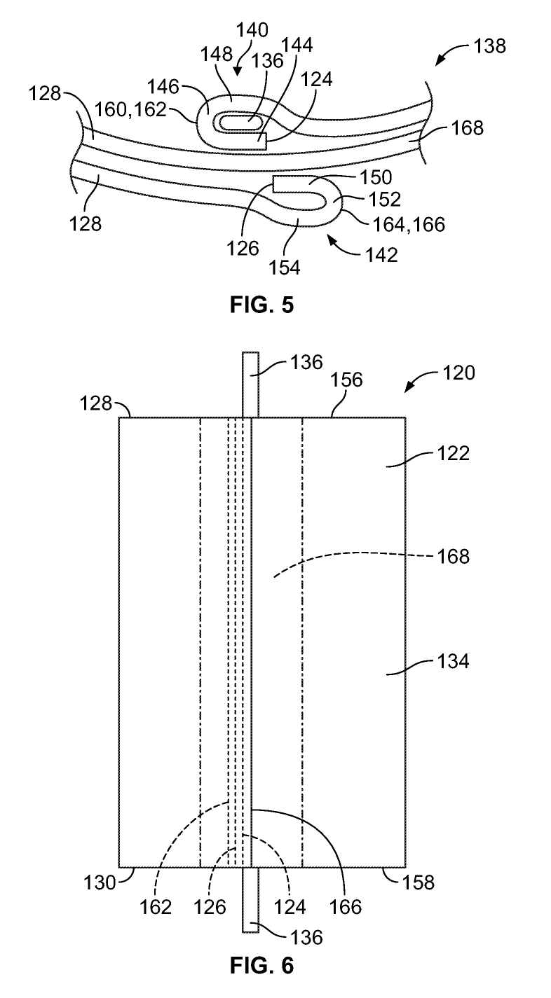

FIG. 4 illustrates a schematic representation a top view of a portion of an exemplary transformer 100 having a shield member 120 according to an illustrated embodiment of the present application. As illustrated, the shield member 120 is positioned in a portion of the gap 118 between the low voltage winding assembly 104 and the high/low barrier 108. As also shown in FIGS. 4 and 5, the shield member 120 includes an overlap portion 138 in which at least opposing first and second edge surfaces 124, 126 of the body portion 122 of the shield member 120 overlap or extend beyond each other. For example, the body portion 122 can have a width between at least the first and second first and second edge surfaces 124, 126 such that, when the shield member 120 is shaped and placed in the gap 118, such as, for, shaped to have a circular cross sectional shape that is sized to fit in the gap 118, the shield member 120 can have excess material that results in at least a portion of the shield member 120 that is at least proximally adjacent to the first edge surface 124 overlapping at least a portion of the shield member 120 that is at least proximally adjacent to the second edge surface 126, and vice versa.

As shown in at least FIGS. 4 and 5, according to the illustrated embodiment, at least a portion of the first and second edge surfaces 124, 126 of the body portion 122 can extend in a direction that is different than the direction at which an adjacent portion of the body portion 122 extends. For example, as shown, the first and second edge surfaces 124, 126 can extend in a direction that is generally opposite or reverse to the direction in which other adjacent portions of the body portion 122 extend. Thus, for example, the first edge surface 124 and the second edge surface 126 can, relative to other adjacent portions of the body portion 122, inwardly extend such that the first and second edge surfaces 124, 126 and at least an adjacent portion of the body portion 122 overlap other adjacent portions of the body portion 122, as shown in FIGS. 4 and 5. Such a configuration can be attained in a variety of manners, including, for example, folding, bending, deforming, or otherwise manipulating at least a portion of the body portion 122 proximally adjacent to the first edge surface 124, as well as a portion of the body portion 122 that is proximally adjacent to the second edge surface 126.

As shown in FIGS. 4 and 5, such a configuration can provide the shield member 120 with a first elbow portion 140 and a second elbow portion 142 at opposing sides of the body portion 122. The first elbow portion 140 can be comprised of a first segment 144, a first elbow 146, and a second segment 148. The first segment 144 can extend in a first direction from the first edge surface 124 to the first elbow 146. The second segment 148 can extend in a second direction from the first elbow 146 and along at least another portion of body portion 122 that is proximally adjacent to the first elbow 146. Moreover, the first elbow 146 can provide a transition that at least facilitates the first and second directions being different directions, including generally opposite directions, such that the body portion 122 along the first and second segments 144, 148 extends in different directions. Further, while the lead 136 can be connected to the shield member 120 in a variety of different manners, and at a variety of different locations, as shown in FIG. 5, according to certain embodiments, the lead 136 can extend into the area between the first and second segments 144, 148 of the first elbow portion 140. Alternatively, according to another embodiment, the lead 136 can be coupled to the second segment 148, as shown in FIG. 4. According to other embodiments, rather than being connected to, or positioned within, the first elbow portion 140, the lead 136 can also be positioned or coupled to the second elbow portion 142 in manners similar to those shown in FIGS. 4 and 5, as well as connected to other portions of the shield member 120. Further, the lead 136 can generally extend away from either an upper area 156 or lower area 158 of the of the shield member 120, both of which configurations are generally represented in FIG. 6.

Similarly, the second elbow portion 142 can be comprised of a third segment 150, and second elbow 152, and a fourth segment 165. The third segment 150 can extend from the second edge surface 126 to the second elbow 152 in a third direction. The fourth segment 165 can extend in a fourth direction from the second elbow 152 and along at least another portion of body portion 122 that is proximally adjacent to the second elbow 152. Moreover, the second elbow 152 can provide a transition that at least facilitates the third and fourth directions being different directions, including generally opposite directions, such that the body portion 122 along the third and fourth segments 150, 154 extends in different directions. Further, according to the embodiment depicted in FIGS. 4 and 5, the first and fourth directions of the first and fourth segments 146, 154, respectively, are generally in similar directions, while the second and third directions of the second and third segments 148, 150, respectively, are generally in similar directions.

According to the illustrated embodiment, an outer surface 160 of the first elbow 146 provides a first end 162 of shield member 120, while an outer surface 164 of the second elbow 152 provides a second end 166 of shield member 120, the first and second ends 162, 166 being generally on opposite sides of the body portion 122 of the shield member 120. Such a configuration accommodates the first and second edge surfaces 124, 126 being offset, recessed, or otherwise displaced away from the first and second ends 162, 166 of the shield member 120. For example, according to certain embodiments, the first and second elbow portions 140, 142 can be configured such that the first end 162 recessed or offset is around at least a half inch (½ inch) from the first end 124, and the second end 166 is recessed or offset around at least a half inch (½ inch) from the second end 126. Additionally, according to certain embodiments, the outer surfaces 160, 164 of the first and second elbows 146, 152 can provide relatively smooth or clean transitions, particularly when compared to the cut first and second edge surfaces 124, 126 and/or the corners and/or edges at or around the first and second edge surfaces 124, 126. According to certain embodiments, the outer surfaces 160, 164 of the first and second elbows 146, 152 can be curved surfaces and/or surfaces that do not introduce another edge or corner in the change in direction of the body portion 122. Further, the relatively smooth or clean surfaces of the outer surfaces 160, 164 of the first and second elbows 146, 152 can, when at least compared to, for example, the sharp corners, edges, and/or cut surfaces of the edge surfaces 124, 126, prevent or minimize the buildup or accumulation of electrical charge at the first and second ends 162, 164 of the shield member 120, and thereby eliminate or minimize the occurrence of partial discharge and the associated deterioration and/or failure of other transformer components.

As shown in FIGS. 4 and 5, according to certain embodiments, the shield member 120 can be sized such that the shield member 120 provides a continuous or uninterrupted boundary or barrier. Moreover, the first elbow portion 140 overlaps at least a portion of the second elbow portion 142 and/or other portions of the body portion 122 adjacent to the second end 166, or vice versa, so that shield member 120 provides a generally enclosed barrier around at least the low voltage winding assembly 104, and moreover, so that there is no exposed opening in the shield member 120. The degree to which the first elbow portion 140 and the second elbow portion 142 overlap each other and/or other portions of the body portion 122 of the shield member 120 in providing the enclosed barrier around at least the low voltage winding assembly 104 can vary. For example, as shown in FIG. 5, according to the certain embodiments, the shield member 120 can be configured such that a portion of the first segment 144 of the first elbow portion 140 overlaps a portion of the third segment 150 of the second elbow portion 142. According to other embodiments, the degree of overlapping may be based on a distance the first end 162 of the first elbow 146 is offset the second edge surface 126 of the body portion 122 and/or a distance the second end 166 of the second elbow 152 is offset the first edge surface 124 of the body portion 122. For example, according to certain embodiments, the shield member 120 can be configured such that the first end 162 of the first elbow 146 is offset the second edge surface 126 of the body portion 122 by at least a half inch (½ inch), similarly the second end 166 of the second elbow 152 is offset the first edge surface 124 of the body portion 122 by at least a half inch (½ inch). Further, according to certain embodiments, such that the first elbow portion 140 overlaps the second elbow portion 142, or vice versa, so that the first end 162 of the shield member 120 is offset from the second end 166 of the shield member 120 by at least one and a half inches (1½ inches).

Additionally, as depicted in FIGS. 4 and 5, the first and second elbows 146, 152 can be configured such that the first and second edge surfaces 124, 126 are both generally confined within the overlapped portions of the shield member 120. For example, as shown in at least FIG. 5, the first and second ends 162, 166 and/or the associated first and third segments 144, 150 are adjacent to each other, such that the first and second edge surfaces 124, 126 are positioned in a region generally between at least the second and fourth segments 152, 154 of the first and second elbow portions 140, 142 respectively. Such positioning may further prevent or minimize partial discharge from the first and/or second edge surfaces 124, 126 that could result in the deterioration or failure of other components of the transformer 100, including deterioration of adjacent insulation.

As shown in FIGS. 4 and 5, the overlapped portions of the shield member 120, such as at least the overlapped portions of the first and second elbows portions 140, 142 and associated first and second edge surfaces 124, 126, can be separated from each other by an insulation body 168. The insulation body 168 can be configured to prevent short circuiting between the overlapped portions of the shield member 120, including short circuiting between the first and second edge surfaces 124, 126. Further, as indicated by FIGS. 4-6, according to the illustrated embodiment, the insulation body 168 can extend radially along the shield member 120 beyond the overlapped portions of the shield member 120. Thus, the configuration of the shield member 120 of the subject application can also prevent or minimize deterioration of the insulation body 168 associated with partial discharge from the edge surfaces 124, 126 of the body portion 122 of the shield member 120 that could otherwise lead to failure of the shield member 120 and/or the transformer 100.

As shown by FIG. 6, the insulation body 168 can also extend along the axial length of the shield member 120, such as, for example, from generally around the upper area 156 of the shield member 120, which can be at or around the upper top edge surface 128 of the body portion 122, to the bottom area 158 of the shield member 120, which can be at or around the bottom edge surface 130 of the body portion 122. Further, the insulation body 168 can be constructed from a variety of electrical insulation materials, such as, for example, electrically resistant cloth or fibers, among other materials. Additionally, the insulation body can have a variety of different sizes, including for example, having a thickness of approximately 0.06 mils.

While the application has been described in connection with what is presently considered to be the most practical and preferred embodiment, it is to be understood that the application is not to be limited to the disclosed embodiment(s), but on the contrary, is intended to cover various modifications and equivalent arrangements included within the spirit and scope of the appended claims, which scope is to be accorded the broadest interpretation so as to encompass all such modifications and equivalent structures as permitted under the law. Furthermore it should be understood that while the use of the word preferable, preferably, or preferred in the description above indicates that feature so described may be more desirable, it nonetheless may not be necessary and any embodiment lacking the same may be contemplated as within the scope of the application, that scope being defined by the claims that follow. In reading the claims it is intended that when words such as “a,” “an,” “at least one” and “at least a portion” are used, there is no intention to limit the claim to only one item unless specifically stated to the contrary in the claim. Further, when the language “at least a portion” and/or “a portion” is used the item may include a portion and/or the entire item unless specifically stated to the contrary.

1. An apparatus comprising:
a body portion having a first edge surface and a second edge surface, the first and second edge surfaces being at opposing sides of the body portion, the body portion constructed of an electrically conductive material and having a shape that includes:
a first end and a second end, the first end outwardly offset from the first edge surface, the second end outwardly offset from the second edge surface, at least portion of the body portion proximally adjacent to the first end overlapping at least a portion of the body portion proximally adjacent to the second end;
an insulation body extending between the overlapped portions of the body portion; and
a lead coupled to the body portion and structured to be in electrical communication with an electrical ground.

2. The apparatus of claim 1, wherein the first end includes a first outer surface and the second end includes a second outer surface, the first and second outer surfaces each providing a relatively smooth transition in a change in direction of at least a portion of the body portion.

3. The apparatus of claim 1, wherein at least a portion of the lead adjacent to the body portion is encased in an insulation material.

4. The apparatus of claim 1, wherein the first edge surface and the second edge surface are positioned between at least a portion of the overlapped portions of the body portion.

5. The apparatus of 1, wherein at least a portion of the lead is positioned between (1) a portion of the body portion and (2) another portion of the body portion that extends from either (a) the first end to the first edge surface or (b) the second end to the second edge surface.

6. The apparatus of claim 1, wherein the body portion has a cylindrical shape.

7. An apparatus comprising:
a body portion having a first elbow portion and a second elbow portion, the body portion constructed from an electrically conductive material, the body portion including a first edge surface and a second edge surface, the first and second edge surfaces being at opposing sides of the body portion,
the first elbow portion comprising a first segment, a second segment, and a first elbow, the first segment extending in a first direction from the first edge surface to the first elbow, the second segment extending in a second direction away from the first elbow, the first direction being different than the second direction,
the second elbow portion comprising a third segment, a fourth segment, and a second elbow, the third segment extending in a third direction from the second edge surface to the second elbow, the fourth segment extending in a fourth direction away from the second elbow, the fourth direction being different than the third direction, at least a portion of the first elbow portion being overlapped by at least a portion of the second elbow portion; and
a lead coupled to the body portion and structured to be in electrical communication with an electrical ground.

8. The apparatus of claim 7, wherein the first elbow defines a first end of the apparatus and the second elbow defines a second end of the apparatus.

9. The apparatus of claim 8, wherein the first elbow includes a first outer surface, the second elbow includes a second outer surface, the first and second outer surfaces being generally curved surfaces.

10. The apparatus of claim 8, further including an insulation body, at least a portion of the insulation body positioned between the overlapped portion of the first elbow portion and the second elbow portion.

11. The apparatus of claim 10, wherein at least a portion of the lead adjacent to the body portion is encased in an insulation material.

12. The apparatus of claim 10, wherein the first and fourth directions are generally in the same direction.

13. The apparatus of claim 12, wherein the second and third directions are generally the same direction.

14. The apparatus of 8, wherein at least a portion of the lead is positioned between one of (1) the first and second segments of the first elbow portion and (2) the third and fourth segments of the second elbow portion.

15. The apparatus of claim 8, wherein the apparatus has a cylindrical shape.

16. An apparatus comprising:
a body portion having a first edge surface and a second edge surface, the first edge surface inwardly recessed from a first end of the body portion, the second edge surface inwardly recessed from a second end of the body portion, the first and second ends each structured to provide a transition in a direction of the body portion, a first segment of the body portion extending between the first edge surface and the first end, a second segment of the body portion extending between the second edge surface and the second end, at least a portion of the first segment overlapped by at least a portion of the second segment, the body portion constructed from an electrically conductive material; and
an insulation body positioned between at least the first segment and the second segment, the insulation body structured to prevent the transfer of an electrical current between at least the first and second segments.

17. The apparatus of claim 16, further including a lead coupled to the body portion, the lead configured to deliver an electrical current from the apparatus to an electrical ground.

18. The apparatus of claim 17, wherein at least a portion of the lead is positioned between one of the first segment and the second segment and another portion of the body portion.

19. The apparatus of claim 16, wherein the first end includes a first outer surface and the second end includes a second outer surface, the first and second outer surfaces being smooth surfaces.

20. The apparatus of claim 16, wherein the electrically conductive material comprises a sheet, foil, or screen that includes at least copper or stainless steel.
